(19) United States
(12) Patent Application Publication
(10) Pub. No.: US 2024/0415033 A1
(43) Pub. Date: Dec. 12, 2024

(54) STORAGE ELEMENT AND STORAGE DEVICE

(71) Applicant: Sony Semiconductor Solutions Corporation, Kanagawa (JP)

(72) Inventors: Tetsuya Mizuguchi, Kanagawa (JP); Katsuhisa Aratani, Kanagawa (JP); Kazuhiro Ohba, Tokyo (JP); Tetsuo Nakayama, Kanagawa (JP); Hiroaki Sei, Kanagawa (JP)

(21) Appl. No.: 18/697,631

(22) PCT Filed: Sep. 27, 2022
(86) PCT No.: PCT/JP2022/035823

§ 371 Date: Apr. 1, 2024

(30) Foreign Application Priority Data
Nov. 16, 2021 (JP) 2021-186576

(51) Int. Cl. H10N 70/00; H10B 63/00; H10B 63/10; H10N 70/20

(52) U.S. Cl. CPC H10N 70/8616; H10B 63/10; H10B 63/24; H10B 63/84; H10N 70/231; H10N 70/8828

(57) ABSTRACT

A storage element includes a first electrode, a resistance change layer, a first interface layer, and a first heat shield layer. The resistance change layer is formed on the first electrode, contains at least tellurium, antimony, and germanium, and is changeable in a resistance value. The first interface layer is formed between the first electrode and the resistance change layer. The first heat shield layer is formed between the first electrode and the first interface layer, has electrical conductivity, contains boron, and blocks heat transfer from the resistance change layer.

### TECHNICAL FIELD

The present disclosure relates to a storage element and a storage device.

### BACKGROUND ART

PTL 1 discloses a phase change memory (PCM) serving as a storage device. A memory cell in the PCM includes an electrically conductive layer, a heat shield layer, an interface layer, a resistance change device, an interface layer, and a heat shield layer. The electrically conductive layer, the heat shield layer, the interface layer, the resistance change device, the interface layer, and the heat shield layer are stacked on one another in sequence. The heat shield layer has electrical conductivity and consists mainly of carbon (C). C has a high thermal resistivity.

### CITATION LIST

### Patent Literature

PTL 1: Japanese Unexamined Patent Application Publication No. 2020-155560

### SUMMARY OF THE INVENTION

In the above-described phase change memory, heat generated due to a repeated operation irreversibly decreases the resistivity of the heat shield layer consisting mainly of C. In other words, an efficiency of heat generation decreases with an increase in thermal conductivity in the heat shield layer, so that an effect of the heat shield layer fails to be sufficiently exhibited. Accordingly, a PCM in which a deterioration due to a repeated operation is effectively reduced or prevented is desired.

The present disclosure provides a storage element and a storage device in which a deterioration due to a repeated operation is effectively reducible or preventable.

A storage element according to a first embodiment of the present disclosure includes a first electrode, a resistance change layer, a first interface layer, and a first heat shield layer. The resistance change layer is formed on the first electrode, contains at least tellurium, antimony, and germanium, and is changeable in resistance value. The first interface layer is formed between the first electrode and the resistance change layer. The first heat shield layer is formed between the first electrode and the first interface layer, has electrical conductivity, contains boron, and blocks heat transfer from the resistance change layer.

A storage device according to a second embodiment of the present disclosure includes a storage element. The storage element includes a first electrode, a resistance change layer, a first interface layer, and a first heat shield layer. The resistance change layer is formed on the first electrode, contains at least tellurium, antimony, and germanium, is changeable in a resistance value. The first interface layer is formed between the first electrode and the resistance change layer. The first heat shield layer is formed between the first electrode and the first interface layer, has electrical conductivity, contains boron, and blocks heat transfer from the resistance change layer.

### BRIEF DESCRIPTION OF DRAWING

FIG. 1 is a perspective view of a relevant part illustrating a schematic configuration of a storage device according to a first embodiment of the present disclosure.

FIG. 2 is a cross-sectional view of a memory cell of the storage device illustrated in FIG. 1.

FIG. 3 is a cross-sectional view of a switching element of the memory cell of the storage device illustrated in FIG. 1.

FIG. 4 is another cross-sectional view of the switching element of the memory cell of the storage device illustrated in FIG. 1.

FIG. 5 is a cross-sectional view of a storage element of the memory cell of the storage device illustrated in FIG. 1.

FIG. 6 is another cross-sectional view of the storage element of the memory cell of the storage device illustrated in FIG. 1.

FIG. 7 is a graph illustrating a relationship between a temperature and a resistivity of a heat shield layer of the storage element illustrated in FIG. 2 to FIG. 6.

FIG. 8 is a graph corresponding to FIG. 7, illustrating a relationship between a temperature and a resistivity of a heat shield layer according to a comparative example.

FIG. 9 is a graph illustrating a relationship between a concentration of carbon relative to boron and the resistivity in the heat shield layer of the storage element illustrated in FIG. 2 to FIG. 6.

FIG. 10 is a graph illustrating a relationship between a concentration of tungsten relative to boron and the resistivity in the heat shield layer of the storage element illustrated in FIG. 2 to FIG. 6.

FIG. 11 is a graph corresponding to FIG. 7, illustrating a relationship between the temperature and the resistivity of the heat shield layer of the storage element illustrated in FIG. 2 to FIG. 6.

FIG. 12 is a graph illustrating a relationship between a concentration of silicon relative to boron and the resistivity in the heat shield layer of the storage element illustrated in FIG. 2 to FIG. 6.

FIG. 13, which corresponds to FIG. 2, is a cross-sectional view of a memory cell of a storage device according to a second embodiment of the present disclosure.

FIG. 14, which corresponds to FIG. 2, is a cross-sectional view of a memory cell of a storage device according to a third embodiment of the present disclosure.

### MODES FOR CARRYING OUT THE INVENTION

In the following, some embodiments of the present disclosure are described in detail with reference to the drawings. It is to be noted that description is made in the following order.

### 1. First Embodiment

In a first embodiment, description is made on an example where the present technology is applied to a storage element and a storage device. Here, a detailed description is made on a configuration of the storage device, a configuration of a memory cell, a configuration of the storage element, and a configuration of a switching element.

### 2. Second Embodiment

In a second embodiment, description is made on a first example where the configuration of the memory cell is altered in the storage device according to the first embodiment.

### 3. Third Embodiment

In a third embodiment, description is made on a second example where the configuration of the memory cell is changed in the storage device according to the first embodiment.

### 4. Other Embodiments

### First Embodiment

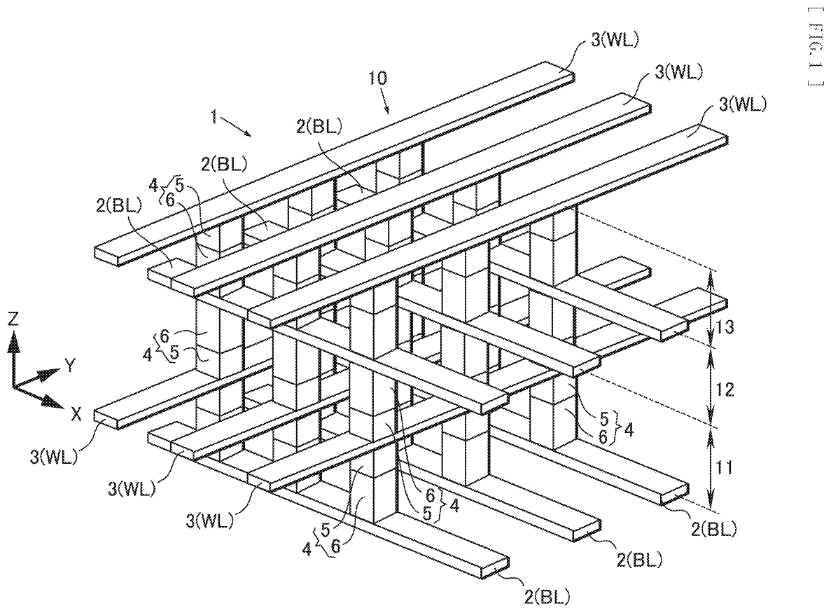

Description is made on a storage element 6 and a storage device 1 according to the first embodiment of the present disclosure with use of FIG. 1 to FIG. 12.

Here, an arrow X direction illustrated in the figures as needed is one of horizontal plane directions when the storage device 1 is placed on a horizontal plane. An arrow Y direction is another one of the horizontal plane directions perpendicular to the arrow X direction. Moreover, an arrow Z direction is an upper direction perpendicular to the arrow X direction and the arrow Y direction. That is to say, the arrow X direction, the arrow Y direction, and the arrow Z direction match an X-axis direction, a Y-axis direction, and a Z-axis direction of a three-dimensional coordinate system, respectively. It should be noted that these directions are drawn merely for the convenience of assisting an understanding of an explanation and by no means limit directions in the present technology.

### [Overall Configuration of Storage Device 1]

### (1) Configuration of Storage Device 1

FIG. 1 illustrates an example of a structure of a memory cell array 10 of the storage device 1 according to the first embodiment of the present disclosure.

The storage device 1 according to the first embodiment is a phase change memory (PCM) herein. The memory cell array 10 of the storage device 1 has a cross point array structure. That is to say, the memory cell array 10 includes a first wiring line 2, a second wiring line 3, and a memory cell 4 between the first wiring line 2 and the second wiring line 3 at a position where the first wiring line 2 and the second wiring line 3 intersect.

The first wiring line 2 is configured as a bit line BL. The first wiring line 2 extends in the arrow X direction and a plurality of such first wiring lines 2 is arranged in the arrow Y direction at a regular interval.

They second wiring line 3 is configured as a word line WL. The second wiring line 3 extends in the arrow Y direction and a plurality of such second wiring lines 3 is arranged in the arrow X direction at a regular interval.

Here, the arrow X direction corresponds to a “first direction” in the present disclosure. Additionally, the arrow Y direction corresponds to a “second direction” in the present disclosure.

Further, a tiered structure is employed for the memory cell array 10. In other words, the first wiring lines 2 and the second wiring lines 3 located in a layer thereabove establish a first tier 11. Additionally, the second wiring lines 3 in the first tier 11 and the first wiring lines 2 located in a layer thereabove establish a second tier 12. Further, the first wiring lines 2 in the second tier 12 and the second wiring lines 3 located in a layer thereabove establish a third tier 13.

The first tier 11 and the second tier 12 share the second wiring lines 3 with each other. The second tier 12 and the third tier 13 share the first wiring lines 2 with each other.

The first wiring lines 2 and the second wiring lines 3 are each coupled to non-illustrated various circuits. Examples of the various circuits include a selection circuit, a writing circuit, a reading circuit, a power circuit, and a control circuit.

Here, only the third tier 13 and the tiers therebelow are illustrated. In the present technology, only the first tier 11, only the first tier 11 and the second tier 12, or only non-illustrated fourth tier and tier thereabove may be established in the memory cell array 10.

### (2) Configuration of Memory Cell 4

In the memory cell array 10, the memory cell 4 is located between the first wiring line 2 and the second wiring line 3 at an intersection between the first wiring line 2 and the second wiring line 3.

FIG. 2 illustrates an example of a cross-sectional structure of the memory cell 4.

The memory cells 4 located between the first wiring lines 2 and the second wiring lines 3 in the first tier 11 to the third tier 13 each include a switching element 5 and a storage element 6.

In the first tier 11, the storage element 6 is stacked on the first wiring line 2 and one end of the storage element 6 is electrically coupled to the first wiring line 2. The switching element 5 is stacked on the storage element 6 and one end of the switching element 5 is electrically coupled to the other end of the storage element 6. The switching element 5 and the storage element 6 are electrically coupled to each other in series. The second wiring line 3 is coupled to a top of the switching element 5 and the other end of the switching element 5 is electrically coupled to the second wiring line 3.

In the second tier 12, the switching element 5 is stacked on the second wiring line 3 and one end of the switching element 5 is electrically coupled to the second wiring line 3. The storage element 6 is stacked on the switching element 5 and one end of the storage element 6 is electrically coupled to the other end of the switching element 5. Likewise, the switching element 5 and the storage element 6 are electrically coupled to each other in series. The first wiring line 2 is coupled to a top of the storage element 6 and the other end of the storage element 6 is electrically coupled to the first wiring line 2.

The third tier 13 is similar in structure to the first tier 11. Here, the switching element 5 and the storage element 6 are formed in a three-dimensional structure to be stacked on each other in the arrow Z direction.

It should be noted that in a case where the fourth tier and a tier thereabove are established, the tiers are in structure in which the first tier 11 and the second tier 12 are alternately and repeatedly stacked on each other in the arrow Z direction.

Additionally, the switching element 5 and the storage element 6 may be in a two-dimensional structure to be coupled to each other in the arrow X direction and the arrow Y direction.

### (3) Configuration of Switching Element 5

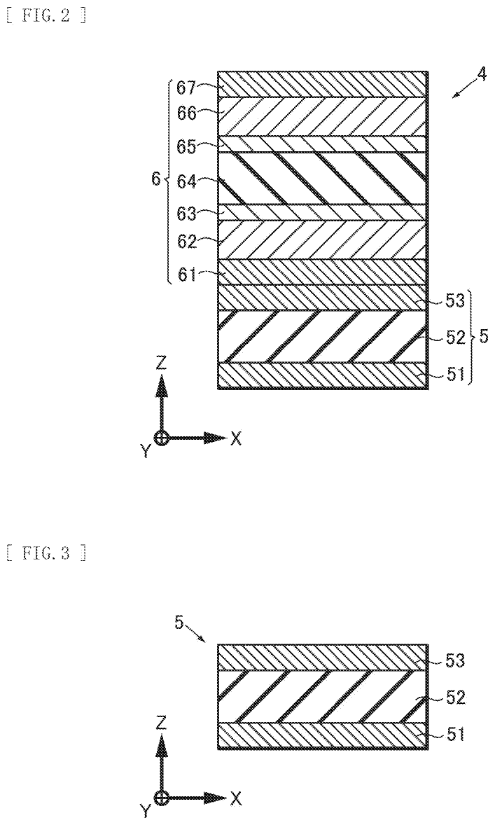

FIG. 3 illustrates an example of a cross-sectional configuration of the switching element 5.

In the first tier 11 or the third tier 13, the switching element 5 of the memory cell 4 includes a first main electrode 51, a switch layer 52, and a second main electrode 53.

The first main electrode 51 is stacked on the storage element 6 and electrically coupled to the storage element 6. The first main electrode 51 includes, for example, one metal material selected from tungsten (W), tungsten nitride (WN), titanium nitride (TiN), carbon (C), copper (Cu), aluminum (Al), molybdenum (Mo), tantalum (Ta), and tantalum nitride (TaN). Alternatively, the first main electrode 51 includes an alloy material including two or more of these metal materials or a silicide material that is a compound of these metal materials and silicon (Si).

The switch layer 52 is stacked on the first main electrode 51 and electrically coupled to the first main electrode 51. The switch layer 52 includes an element in the 16th group in the periodic table, specifically, at least one chalcogen (Chalcogens) element selected from tellurium (Te), selenium (Se), and sulfur (S).

In the switching element 5 having an ovonic threshold switch (OTS: Ovonic Threshold Switch) phenomenon, it is preferable that the switch layer 52 undergo no phase change with an amorphous structure being maintained even when a voltage bias of a switching operation is applied. It is possible to produce the OTS phenomenon with an increased stability with an increase in the stability of the amorphous structure.

The switch layer 52 may further include at least one accessory element selected from boron (B), gallium (Ga), C, germanium (Ge), and Si in addition to the above-described chalcogen element. It is preferable that the switch layer 52 further include nitrogen (N) and arsenic (As).

Increasing an application voltage to a predetermined threshold voltage (a switching threshold voltage) or greater causes the switch layer 52 to transition into a low resistance state without a phase change between an amorphous phase and a crystalline phase. In contrast, decreasing the application voltage to a voltage lower than the above-described threshold voltage causes the switch layer 52 to transition into a high resistance state.

That is to say, no phase change occurs in the switch layer 52 even when a voltage pulse or a current pulse is applied from a non-illustrated power circuit (a pulse supply circuit) via the first main electrode 51 and the second main electrode 53. Additionally, in the switch layer 52, no memory operation occurs; for example, no conduction path formed by the movement of ions responsive to the application of a voltage remains even after the application voltage disappears.

Further, when a first application voltage at which a voltage of the first main electrode 51 becomes higher than a voltage of the second main electrode 53 is applied to between the first main electrode 51 and the second main electrode 53, the switch layer 52 transitions into the low resistance state as the absolute value of the first application voltage increases to a first threshold voltage or greater. In contrast, the switch layer 52 transitions into the high resistance state as the absolute value of the first application voltage decreases to a voltage lower than the first threshold voltage.

Reversely, even when a second application voltage at which the voltage of the second main electrode 53 becomes higher than the voltage of the first main electrode 51 is applied to between the first main electrode 51 and the second main electrode 53, the switch layer 52 transitions into the low resistance state as the absolute value of the second application voltage increases to a second threshold voltage or greater. In contrast, the switch layer 52 transitions into the high resistance state as the absolute value of the second application voltage decreases to a voltage lower than the second threshold voltage.

The second main electrode 53 is stacked on the switch layer 52 and electrically coupled to the switch layer 52. Here, the second main electrode 53 includes the same metal material, alloy material, or silicide material as the first main electrode 51.

The second main electrode 53 is formed by a layer independent relative to the second wiring line 3 in the first embodiment. It should be noted that the second main electrode 53 may be formed by the second wiring line 3. In other words, the second main electrode 53 and the second wiring line 3 are integrally formed.

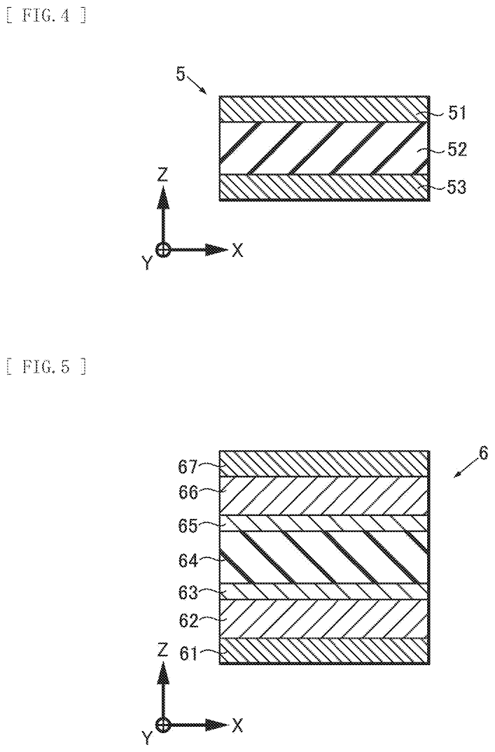

FIG. 4 illustrates an example of another cross-sectional configuration of the switching element 5.

In the second tier 12, the switching element 5 of the memory cell 4 includes the first main electrode 51, the switch layer 52, and the second main electrode 53 as the switching element 5 in the first tier 11 or the third tier 13. The switching element 5 is opposite in stacking order to the switching element 5 in the first tier 11 or the third tier 13 and thus the switching element 5 includes the second main electrode 53, the switch layer 52, and the first main electrode 51 stacked on one another in sequence.

### (4) Configuration of Storage Element 6

FIG. 5 illustrates an example of a cross-sectional configuration of the storage element 6.

The storage element 6 includes a first electrode 61, a first heat shield layer 62, a first interface layer 63, a resistance change layer 64, a second interface layer 65, a second heat shield layer 66, and a second electrode 67.

Here, the resistance change layer 64 is formed on the first electrode 61 with the first interface layer 63 being formed between the first electrode 61 and the resistance change layer 64. The first heat shield layer 62 is formed between the first interface layer 63 and the resistance change layer 64. Likewise, the second electrode 67 is formed on the resistance change layer 64 with the second interface layer 65 being formed between the second electrode 67 and the resistance change layer 64. The second heat shield layer 66 is formed between the second interface layer 65 and the resistance change layer 64.

A structure is described in detail below.

In the first tier 11 or the third tier 13, the first electrode 61 is stacked on the first wiring line 2 and electrically coupled to the first wiring line 2. The first electrode 61 includes a material similar to, for example, that of the first main electrode 51 of the switching element 5.

Additionally, the first electrode 61 is formed as a layer independent of or formed integrally with the first wiring line 2.

The first heat shield layer 62 has electrical conductivity and blocks heat transfer from the resistance change layer 64 to the first electrode 61. In the storage element 6 according to the first embodiment, B is contained in the first heat shield layer 62. Likewise, B is contained in the second heat shield layer 66. Configurations of the first heat shield layer 62 and the second heat shield layer 66 will be described in detail later.

The first interface layer 63 is stacked on the first heat shield layer 62. The first interface layer 63 has electrical conductivity and reduces a change in the composition of the resistance change layer 64. The first interface layer 63 includes, for example, W or WN. A thickness of the first interface layer 63 is, for example, greater than or equal to 1 nm and less than or equal to 15 nm.

The resistance change layer 64 is stacked on the first interface layer 63 and electrically coupled to the first interface layer 63. The resistance value of the resistance change layer 64 changes and information “1” or information “0” is to be stored in accordance with the change in the resistance value.

The resistance change layer 64 includes a phase change material containing at least Te, antimony (Sb), and Ge. The resistance change layer 64 may further include C, Si, indium (In), or the like.

A thickness of the resistance change layer 64 is, for example, a thickness in a range greater than or equal to 10 nm and less than or equal to 40 nm.

In the memory cell 4, an electric current flows through the storage element 6 and Joule heat generated at the time causes a phase change to occur in the resistance change layer 64. An application of a voltage greater than or equal to a threshold voltage to the storage element 6 with the resistance change layer 64 being in an amorphous state causes a large electric current to flow to generate Joule heat, raising a temperature of the resistance change layer 64. Further, the temperature of the resistance change layer 64 is kept within a crystallization temperature region by controlling the applied voltage, which causes the resistance change layer 64 to transition into a polycrystal state. The resistance change layer 64 thus goes into the low resistance state.

Additionally, application of a voltage to the storage element 6 with the resistance change layer 64 being in the polycrystal state causes a large electric current to flow through the resistance change layer 64, melting the resistance change layer 64. In addition, the resistance change layer 64 is rapidly cooled by precipitously lowering the voltage, which makes it possible to cause the resistance change layer 64 to transition into the amorphous state. This state is the high resistance state.

Application of a voltage to both ends of the memory cell 4 (between the first electrode 61 and the second main electrode 53) causes the switching element 5 to go into the low resistible state when a partial voltage applied to the switching element 5 exceeds the threshold voltage of the switching element 5. This causes an electric current to flow through the storage element 6 when a sufficient voltage is applied to the storage element 6. The flow of the electric current causes Joule heat to be generated to crystallize the storage element 6, putting the resistance change layer 64 into the low resistible state, or so-called set state.

In contrast, removal of the voltage applied to both ends of the memory cell 4 causes the switching element 5 to return to the high resistance state. At this time, the resistance change layer 64 remains in the crystallized state and the low resistance state of the storage element 6 is maintained. When a voltage is again applied to the memory cell 4 and a partial voltage applied to the switching element 5 exceeds the threshold voltage of the switching element 5, the switching element 5 goes into the low resistible state.

This causes an electric current to flow through the storage element 6 in the low resistance state. Joule heat in a temperature region for the resistance change layer 64 to melt is added and then the voltage is precipitously lowered, which rapidly cools the resistance change layer 64. As a result, the resistance change layer 64 becomes amorphous and goes into the high resistance state, or so-called reset state.

At this time, the switching element 5 goes back into the high resistance state and the storage element 6 remains in the amorphous state with the high resistance state being maintained.

For the switching element 5 including the phase change material, it is required to reduce an electric current (a reset current) necessary for a reset operation in terms of low power consumption. The first heat shield layer 62 and the second heat shield layer 66 are provided above and below the resistance change layer 64 including a phase change material, respectively. The first heat shield layer 62 and the second heat shield layer 66 each have electrical conductivity and include a material with a low thermal conductivity. This makes it possible to improve an efficiency of heat generation in the resistance change layer 64. By virtue of an improvement in the efficiency of heat generation in the resistance change layer 64, a temperature necessary for the reset operation is allowed to be reached by a supply of a low electric current.

It is thus possible to reduce the electric current and, consequently, lower the power consumption. Accordingly, it is significantly important to select the material of each of the first heat shield layer 62 and the second heat shield layer 66 in order to improve the efficiency of heat generation.

The second interface layer 65 is stacked on the resistance change layer 64 and electrically coupled to the resistance change layer 64. The second interface layer 65 is formed similarly in material and thickness to the first interface layer 63.

The second heat shield layer 66 is stacked on the second interface layer 65 and electrically coupled to the second interface layer 65. The second heat shield layer 66 is formed similarly in material and thickness to the first heat shield layer 62.

The second electrode 67 is then stacked on the second heat shield layer 66 and electrically coupled to the second heat shield layer 66. The second electrode 67 includes a material similar to, for example, that of the first main electrode 51 of the switching element 5.

Additionally, the second electrode 67 is formed as a layer independent of or formed integrally with the second wiring line 3.

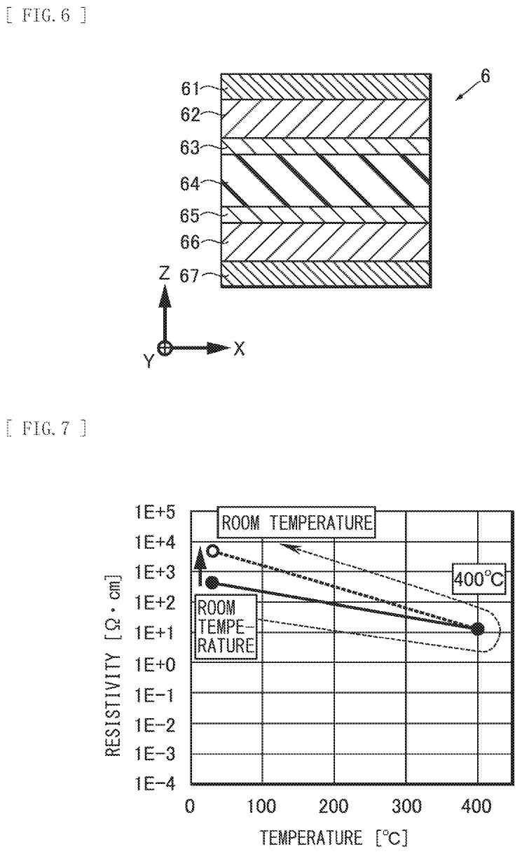

FIG. 6 illustrates an example of another cross-sectional configuration of the storage element 6.

In the second tier 12, the storage element 6 of the memory cell 4 includes the first electrode 61, the first heat shield layer 62, the first interface layer 63, the resistance change layer 64, the second interface layer 65, the second heat shield layer 66, and the second electrode 67 as the storage element 6 in the first tier 11 or the third tier 13. The storage element 6 is opposite in stacking order to the storage element 6 in the first tier 11 or the third tier 13: the second electrode 67, the second heat shield layer 66, the second interface layer 65, the resistance change layer 64, the first interface layer 63, the first heat shield layer 62, and the first electrode 61 are stacked on one another in sequence.

### (5) Configurations of First Heat Shield Layer 62 and Second Heat Shield Layer 66

A detailed description is made on the first heat shield layer 62 and the second heat shield layer 66.

In order to select the materials of the first heat shield layer 62 and the second heat shield layer 66, changes in resistivity with temperature histories of the materials were examined. As for a metal material, a thermal conductivity is correlated with a resistivity of the metal material. Additionally, Joule heat changes with the resistivity of the metal material. Accordingly, the selection of the materials serves as an important index for knowing the efficiency of heat generation.

### Comparative Example

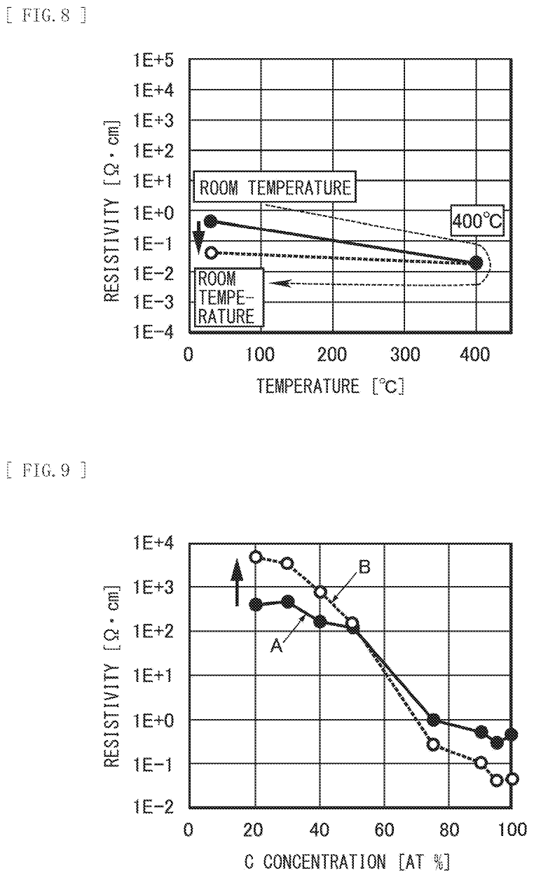

FIG. 8 illustrates a relationship between a temperature and a resistivity of a heat shield layer according to a comparative example. The horizontal axis represents the temperature [° C.] and the vertical axis represents the resistivity [Ω·cm].

C was used for the heat shield layer. The heat shield layer was formed with a thickness of 10 nm or greater. A four-terminal resistance measurement was performed with a change in the temperature in a heating oven and a change in the resistivity of the heat shield layer with a temperature history was measured.

FIG. 8 illustrates a change in the resistivity of the heat shield layer during a process where the temperature in the heating oven increased from room temperature to 400° C. and then returned again to room temperature.

The resistivity of the heat shield layer decreases with an increase in the temperature. Then, the temperature decreases to room temperature and the resistivity slightly increases during a process of the decrease in the temperature.

However, the resistivity of the heat shield layer does not return to a level obtained at room temperature before heating. A resistivity after heating decreases by an order of magnitude, approximately, with respect to the resistivity before heating.

There is a possibility that an actual operation temperature of a storage element exceeds, for example, 600° C. Thus, the resistivity of the heat shield layer is expected to further decrease.

As for the heat shield layer according to the comparative example, the resistivity after heating decreases and thus the thermal conductivity increases. Hence, in a storage layer, an effect in confining the generated Joule heat in the layer decreases and the amount of generation of the Joule heat in the layer also decreases. This causes a decrease in the efficiency of heat generation in the storage element. With a decrease in the efficiency of heat generation with a temperature history attributed to a repeated operation of the storage element, an effect in reducing a reset current also decreases, which leads to a failure in the reset operation.

In contrast, heating to an operation temperature or higher in advance is likely to reduce a change in the resistivity due to a subsequent heat history. However, in a case where a heating temperature exceeds, for example, 600° C., a semiconductor wafer as a whole is exposed to a high temperature higher than or equal to the operation temperature during a production process, the semiconductor wafer including a chip on which an electric circuit is produced. Accordingly, a solution based on adjustment of temperature is not practical.

### EXAMPLE

FIG. 7 illustrates a relationship between a temperature and a resistivity of the first heat shield layer 62 according to the first embodiment. The horizontal axis represents the temperature [° C.] and the vertical axis represents the resistivity [0-cm].

Boron carbide (B4C) was used for the first heat shield layer 62. In other words, as compared with the material of the heat shield layer of the comparative example, B is contained in the first heat shield layer 62. B is higher in resistance value than C. Additionally, mixing of an element such as oxygen (O₂) in the first heat shield layer 62 is excluded. This is for the purpose of avoiding an adverse influence on a resistance change characteristic of the resistance change layer 64. The first heat shield layer 62 was formed with a thickness of 10 nm or greater. A four-terminal resistance measurement was performed with a change in the temperature in a heating oven and a change in the resistivity of the first heat shield layer 62 with a temperature history was measured as in the comparative example.

It should be noted that the second heat shield layer 66 is similar in configuration to the first heat shield layer 62 and the description thereof is omitted, accordingly.

FIG. 7 illustrates a change in the resistivity of the first heat shield layer 62 during a process where a temperature in a heating oven increased from room temperature to 400° C. and then returned again to room temperature.

The resistivity of first heat shield layer 62 decreases with an increase in the temperature. Then, the temperature decreases to room temperature and the resistivity increases during a process of the decrease in the temperature.

Moreover, a resistivity of the first heat shield layer 62 after heating increases by an order of magnitude, approximately, with respect to the resistivity of the first heat shield layer 62 obtained at room temperature before heating. This tendency is common to the second heat shield layer 66.

In other words, in the storage element 6 according to the first embodiment, the resistivity after heating increases and thus the thermal conductivity decreases. Hence, in a storage layer, an effect in confining the generated Joule heat in the layer increases and the amount of generation of the Joule heat in the layer also increases. This improves the efficiency of heat generation in the storage element 6. Therefore, the efficiency of heat generation increases with a temperature history attributed to a repeated operation of the storage element 6, which makes it possible to improve even an effect in reducing a reset current and effectively reduce or prevent a failure in the reset operation.

Further, in the storage element 6 according to the first embodiment, it is not necessary to perform heating to a temperature higher than or equal to the operation temperature in advance during a production process. This allows the storage element 6 and, consequently, the storage device 1 to be very practically producible.

FIG. 9 illustrates a relationship between a C concentration and the resistivity of the first heat shield layer 62 according to the first embodiment. The horizontal axis represents a C concentration [atom %] relative to a B concentration and the vertical axis represents the resistivity [Ω·cm].

The first heat shield layer 62 further contains C in addition to B. As illustrated in FIG. 9, the resistivity changes with the C concentration contained in the first heat shield layer 62. Data before heating is labeled with a reference sign “A.” Data after heating is labeled with a reference sign “B.”

The resistivity of the first heat shield layer 62 decreases with an increase in the C concentration irrespective of before heating or after heating. However, at a C concentration in a range greater than or equal to 20 atom % and less than or equal to 50 atom % relative to the B concentration, the resistivity of the first heat shield layer 62 after heating increases with respect to the resistivity of the first heat shield layer 62 before heating. In particular, at a C concentration in a range greater than or equal to 20 atom % and less than or equal to 35 atom % relative to the B concentration, the resistivity of the first heat shield layer 62 after heating increases by an order of magnitude, approximately, with respect to that before heating.

Accordingly, C is contained in the first heat shield layer 62, which makes it possible to effectively reduce or prevent a decrease in the efficiency of heat generation due to the repeated operation of the storage element 6.

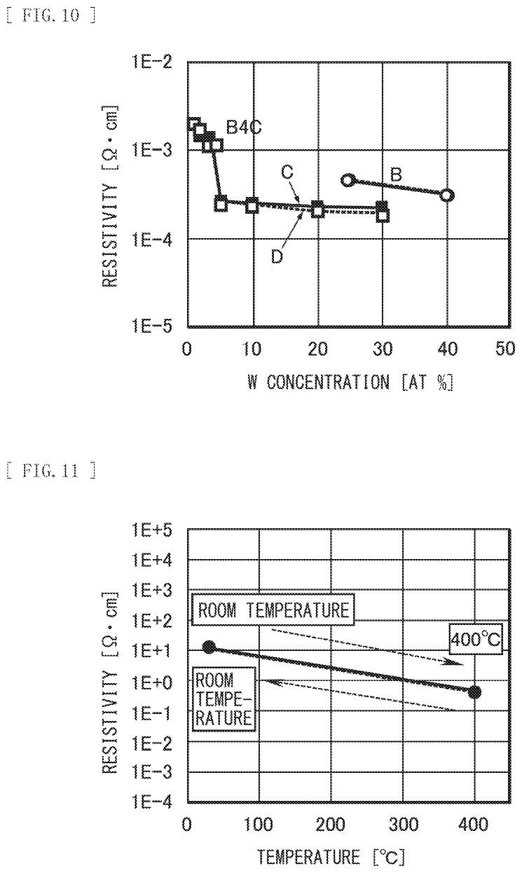

FIG. 10 illustrates a relationship between a W concentration and the resistivity of the first heat shield layer 62 according to the first embodiment. The horizontal axis represents a W concentration [atom %] relative to the B concentration and the vertical axis represents the resistivity [Ω·cm].

B4C is used for the first heat shield layer 62 and the first heat shield layer 62 further contains W in addition to B. As illustrated in FIG. 10, the resistivity changes with the W concentration contained in the first heat shield layer 62. Data before heating is labeled with a reference sign “C.” Data after heating is labeled with a reference sign “D.”

The resistivity of the first heat shield layer 62 decreases with an increase in the W concentration irrespective of before heating or after heating. However, at a W concentration greater than or equal to 1 atom % and less than 5 atom % relative to the B concentration, the resistivity of the first heat shield layer 62 after heating slightly increases with respect to the resistivity of the first heat shield layer 62 before heating. Accordingly, W is contained in the first heat shield layer 62, which makes it possible to effectively reduce or prevent a decrease in the efficiency of heat generation due to the repeated operation of the storage element 6.

Here, B4C is used for the first heat shield layer 62; however, even though pure B is used as a base of the first heat shield layer 62 as illustrated in FIG. 10, the resistivity also decreases with an increase in the temperature by virtue of an increase in the W concentration. It should be noted that almost no change in the resistivity between before and after heating is observed in this case.

A change in operation conditions of the storage element 6 makes it difficult to control the resistivity. Accordingly, it is desirable that a change in the resistivity due to heat be small. Further mixing C with B4C, mixing W with B4C, or further mixing C and W with B4C as described above allows a change in the resistivity of the first heat shield layer 62 due to heat to be small.

FIG. 11 illustrates a relationship between the temperature and resistivity of the first heat shield layer 62 according to the first embodiment. The horizontal axis represents the temperature [° C.] and the vertical axis represents the resistivity [Ω·cm].

FIG. 11 illustrates a change in the resistivity of the first heat shield layer 62 during a process where a temperature in a heating oven increased from room temperature to 400° C. and then returned again to room temperature. The resistivity of first heat shield layer 62 decreases with an increase in the temperature. Then, the temperature decreases to room temperature and the resistivity increases during a process of the decrease in the temperature.

Moreover, the resistivity of the first heat shield layer 62 after heating hardly changes with respect to the resistivity of the first heat shield layer 62 obtained at room temperature before heating. Acquirement of such a characteristic stabilizes the efficiency of heat generation by the repeated operation of the storage element 6, which makes it possible to prevent a failure in the reset operation.

The first heat shield layer 62 is not necessarily, for example, a single-layer film of B4C; for example, B4C serving as a first film and C serving as a second film may be alternately stacked on each other or B4C and B may be alternately stacked on each other. At this time, settings are applied to the first heat shield layer 62 to cause an average composition in the layer to be the same.

Further, the first heat shield layer 62 may contain Si, Ge, or both in B or B4C.

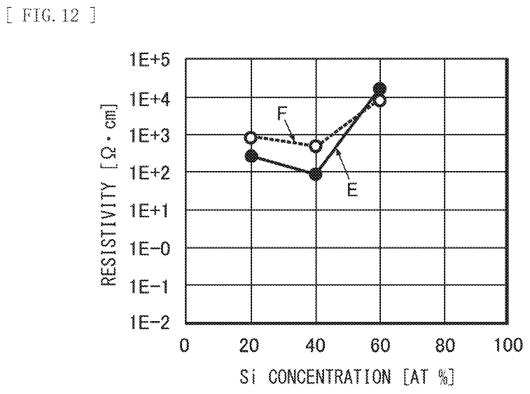

Here, a change in the resistivity of the first heat shield layer 62 when Si was contained was checked as an example. FIG. 12 illustrates a relationship between an Si concentration and the resistivity of the first heat shield layer 62 according to the first embodiment. The horizontal axis represents an Si concentration [atom %] relative to the B concentration and the vertical axis represents the resistivity [Ω·cm].

B is used for the first heat shield layer 62 and the first heat shield layer 62 further contains Si in addition to B. As illustrated in FIG. 12, the resistivity changes with the Si concentration contained in the first heat shield layer 62. Data before heating is labeled with a reference sign “E.” Data after heating is labeled with a reference sign “F.”

At an Si concentration greater than or equal to 20 atom % and less than 40 atom % relative to the B concentration, the resistivity of the first heat shield layer 62 decreases with an increase in the Si concentration irrespective of before heating or after heating. In contrast, at an Si concentration greater than or equal to 40 atom % and less than 60 atom % relative to the B concentration, the resistivity of the first heat shield layer 62 increases with an increase in the Si concentration.

However, at an Si concentration greater than or equal to 20 atom % and less than 60 atom % relative to the B concentration, the resistivity of the first heat shield layer 62 after heating is higher than the resistivity of the first heat shield layer 62 before heating.

Accordingly, Si is contained in the first heat shield layer 62, which makes it possible to effectively reduce or prevent a decrease in the efficiency of heat generation due to the repeated operation of the storage element 6.

Additionally, assuming that the thickness of the resistance change layer 64 is 30 nm, the thickness of the first heat shield layer 62 is formed at a thickness, for example, in a range greater than or equal to 1 nm and less than or equal to 15 nm. The first heat shield layer 62 formed to have a thickness greater than or equal to 1 nm makes it possible to provide an effect as a heat shield layer. Meanwhile, the formation at a thickness of 15 nm or less reduces a height of the memory cell 4, which facilitates a machining on a production process. That is to say, the thickness of the first heat shield layer 62 is less than or equal to half of the thickness of the resistance change layer 64.

Additionally, when a low-level resistivity of the phase change material of the resistance change layer 64 is, for example, in a range from 2×10⁻³ to 5×10⁻¹ [Ω·cm] depending on the material, the first heat shield layer 62 exhibits a comparable resistance. Specifically, when the thickness of the first heat shield layer 62 is formed at the above-described thickness, for example, in a range greater than or equal to 1 nm and less than or equal to 15 nm, the resistivity of the first heat shield layer 62 is, for example, in a range from 2=10 to 2=10⁻³ [Ω·cm].

Additionally, a resistance of the first heat shield layer 62 is adjustable by mixing a metal material including W, nitrogen, or the like in accordance with a resistance of the resistance change layer 64 unless the characteristics are impaired.

### Workings and Effects

The storage element 6 according to the first embodiment includes the first electrode 61, the resistance change layer 64, the first interface layer 63, and the first heat shield layer 62 as illustrated in FIG. 1 to FIG. 7 and FIG. 9.

The resistance change layer 64 is formed on the first electrode 61, contains at least Te, Sb, and Ge, and is changeable in resistance value. The first interface layer 63 is formed between the first electrode 61 and the resistance change layer 64. The first heat shield layer 62 is formed between the first electrode 61 and the first interface layer 63, has electrical conductivity, and blocks heat transfer from the resistance change layer 64.

Here, the first heat shield layer 62 contains B. This increases the resistivity of the first heat shield layer 62 after heating, which allows the first heat shield layer 62 to improve the efficiency of heat generation in the resistance change layer 64. Therefore, it is possible to effectively reduce or prevent a deterioration due to the repeated operation of the storage element 6.

Additionally, the storage element 6 further includes the second electrode 67, the second interface layer 65, and the second heat shield layer 66 as illustrated in FIG. 1 to FIG. 7 and FIG. 9.

The second electrode 67 is formed on the resistance change layer 64 on an opposite side to the first electrode 61. The second interface layer 65 is formed between the second electrode 67 and the resistance change layer 64. The second heat shield layer 66 is formed between the second electrode 67 and the second interface layer 65, has electrical conductivity, and blocks heat transfer from the resistance change layer 64.

Here, the second heat shield layer 66 contains B. This increases the resistivity of the second heat shield layer 66 after heating, which allows the second heat shield layer 66 to improve the efficiency of heat generation in the resistance change layer 64. Therefore, it is possible to effectively reduce or prevent a deterioration due to the repeated operation of the storage element 6.

Additionally, in the storage element 6, the first heat shield layer 62, the second heat shield layer 66, or both contain C as illustrated in FIG. 9. This causes the first heat shield layer 62, the second heat shield layer 66, or both to be increased in resistivity after heating, which makes it possible to improve the efficiency of heat generation in the resistance change layer 64. Therefore, it is possible to effectively reduce or prevent a deterioration due to the repeated operation of the storage element 6.

Additionally, in the storage element 6, the first heat shield layer 62, the second heat shield layer 66, or both contain C in a range greater than or equal to 20 atom % and less than or equal to 50 atom % relative to B as illustrated in FIG. 9.

This causes the first heat shield layer 62, the second heat shield layer 66, or both to be increased in resistivity after heating by an order of magnitude, approximately, which makes it possible to improve the efficiency of heat generation in the resistance change layer 64. Therefore, it is possible to more effectively reduce or prevent a deterioration due to the repeated operation of the storage element 6.

Additionally, in the storage element 6, the first heat shield layer 62, the second heat shield layer 66, or both contain Si or Ge. For example, at an Si concentration greater than or equal to 20 atom % and less than 60 atom %, the resistivity of the first heat shield layer 62 after heating is higher than the resistivity of the first heat shield layer 62 before heating as illustrated in FIG. 12.

As seen from the above, containing another element in addition to B causes the resistivity of the first heat shield layer 62, the second heat shield layer 66, or both after heating to be comparable to the resistivity before heating as illustrated in FIG. 11, which makes it possible to keep the efficiency of heat generation in the resistance change layer 64 constant. Therefore, it is possible to more effectively reduce or prevent a deterioration due to the repeated operation of the storage element 6.

Additionally, in the storage element 6, the first heat shield layer 62, the second heat shield layer 66, or both contain W, as illustrated in FIG. 10. The concentration of W is in a range greater than or equal to 1 atom % and less than 5 atom % relative to B.

This causes the first heat shield layer 62, the second heat shield layer 66, or both to be increased in resistivity after heating, which makes it possible to improve the efficiency of heat generation in the resistance change layer 64. Therefore, it is possible to effectively reduce or prevent a deterioration due to the repeated operation of the storage element 6.

Additionally, in the storage element 6, the first heat shield layer 62, the second heat shield layer 66, or both include a single-layer film containing B. Alternatively, the first heat shield layer 62, the second heat shield layer 66, or both include a composite film in which a first film containing B and a second film containing no B are stacked.

This causes the resistivity of the first heat shield layer 62, the second heat shield layer 66, or both after heating to be comparable to the resistivity before heating as illustrated in FIG. 11, which makes it possible to keep the efficiency of heat generation in the resistance change layer 64 constant. Therefore, it is possible to more effectively reduce or prevent a deterioration due to the repeated operation of the storage element 6.

Additionally, in the storage element 6, the thickness of the first heat shield layer 62, the second heat shield layer 66, or both is less than or equal to half of the thickness of the resistance change layer 64.

This makes it possible to more effectively reduce or prevent a deterioration due to the repeated operation of the storage element 6 and reduce the height of the storage element 6. Therefore, it is possible to facilitate a machining during the production process of the memory cell 4.

Further, the storage device 1 includes the storage element 6 as illustrated in FIG. 1. This allows the storage device 1 to achieve workings and effects similar to the workings and effects achievable by the storage element 6.

### Second Embodiment

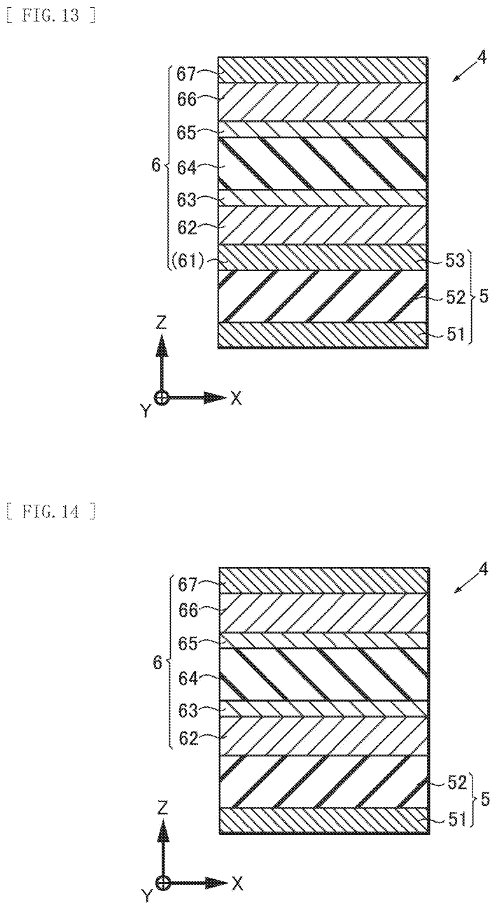

Description is made on the storage element 6 and the storage device 1 according to a second embodiment of the present disclosure with use of FIG. 13.

It should be noted that the same reference signs are used to refer to the same or substantially the same components as the components of the storage element 6 and the storage device 1 according to the first embodiment in the present embodiment and a subsequent embodiment and a redundant description is omitted.

### [Configurations of Storage Element 6 and Storage Device 1]

FIG. 13 illustrates an example of a cross-sectional structure of the memory cell 4.

In the storage element 6 and the storage device 1 according to the second embodiment, the first electrode 61 is omitted from the storage element 6 of the memory cell 4 of the storage element 6 and the storage device 1 according to the first embodiment. In other words, the first heat shield layer 62 of the storage element 6 is directly coupled to the second main electrode 53 of the switching element 5.

Incidentally, as stated another way, the second main electrode 53 of the switching element 5 may be omitted from the configuration.

The components other than the above-described components are the same as the components of the storage element 6 and the storage device 1 according to the first embodiment.

### Workings and Effects

The storage element 6 and the storage device 1 according to the second embodiment are allowed to achieve workings and effects similar to the workings and effects achievable by the storage element 6 and the storage device 1 according to the first embodiment.

Additionally, in the storage element 6 and the storage device 1, the first electrode 61 of the storage element 6 is omitted. This makes it possible to reduce the height of the memory cell 4, allowing for further facilitating a machining more during the production process of the memory cell 4.

### Third Embodiment

Description is made on the storage element 6 and the storage device 1 according to a third embodiment of the present disclosure with use of FIG. 14.

### [Configurations of Storage Element 6 and Storage Device 1]

FIG. 14 illustrates an example of a cross-sectional structure of the memory cell 4. In the storage element 6 and the storage device 1 according to the third embodiment, the first electrode 61 is omitted from the storage element 6 and the storage element 6 of the memory cell 4 of the storage device 1 according to the first embodiment and, further, the second main electrode 53 is omitted from the switching element 5. In other words, the first heat shield layer 62 of the storage element 6 is directly coupled to the switch layer 52 of the switching element 5.

The components other than the above-described components are the same as the components of the storage element 6 and the storage device 1 according to the first embodiment.

### Workings and Effects

The storage element 6 and the storage device 1 according to the third embodiment are allowed to achieve workings and effects similar to the workings and effects achievable by the storage element 6 and the storage device 1 according to the first embodiment.

Additionally, in the storage element 6 and the storage device 1, the first electrode 61 of the storage element 6 and the second main electrode 53 of the switching element 5 are omitted. This makes it possible to further reduce the height of the memory cell 4, allowing for further facilitating a machining during the production process of the memory cell 4.

### Other Embodiments

The present technology is not limited to the above-described embodiments and may be modified in various manners without departing from the gist thereof.

In the present disclosure, a storage element includes a first electrode, a resistance change layer, a first interface layer, and a first heat shield layer.

The resistance change layer is formed on the first electrode, contains at least Te, Sb, and Ge, and is changeable in resistance value. The first interface layer is formed between the first electrode and the resistance change layer. The first heat shield layer is formed between the first electrode and the first interface layer, has electrical conductivity, and blocks heat transfer from the resistance change layer.

Here, the first heat shield layer contains B. This increases the resistivity of the first heat shield layer after heating, which allows the first heat shield layer to improve the efficiency of heat generation in the resistance change layer. Therefore, it is possible to effectively reduce or prevent a deterioration due to the repeated operation of the storage element.

Additionally, a storage device includes a storage element. The storage element includes a first electrode, a resistance change layer, a first interface layer, and a first heat shield layer.

The resistance change layer is formed on the first electrode, contains at least Te, Sb, and Ge, and is changeable in resistance value. The first interface layer is formed between the first electrode and the resistance change layer. The first heat shield layer is formed between the first electrode and the first interface layer, has electrical conductivity, and blocks heat transfer from the resistance change layer.

Here, the first heat shield layer contains B. This increases the resistivity of the first heat shield layer after heating, which allows the first heat shield layer to improve the efficiency of heat generation in the resistance change layer. Therefore, it is possible to effectively reduce or prevent a deterioration due to a repeated operation of the storage device.

### Configuration of the Present Technology

The present technology includes the following configuration. By virtue of providing the following configuration, it is possible to provide a storage element and a storage device in which a deterioration due to a repeated operation is effectively reducible or preventable.

(1)

A storage element including:
a first electrode;
a resistance change layer that is formed on the first electrode, contains at least tellurium, antimony, and germanium, and is changeable in a resistance value; a first interface layer that is formed between the first electrode and the resistance change layer; and
a first heat shield layer that is formed between the first electrode and the first interface layer, has electrical conductivity, contains boron, and blocks heat transfer from the resistance change layer.
   (2)

The storage element according to (1), further including:
a second electrode that is formed on the resistance change layer on an opposite side to the first electrode;
a second interface layer that is formed between the second electrode and the resistance change layer; and
a second heat shield layer that is formed between the second electrode and the second interface layer, has electrical conductivity, and blocks heat transfer from the resistance change layer.
   (3)

The storage element according to (2), in which
the second heat shield layer contains boron.
   (4)

The storage element according to (3), in which
the first heat shield layer, the second heat shield layer, or both contain carbon.
   (5)

The storage element according to any one of (1) to (4), in which
the first heat shield layer contains carbon in a range greater than or equal to 20 atomic percent and less than or equal to 50 atomic percent relative to boron.
   (6)

The storage element according to any one of (3) to (5), in which
the second heat shield layer contains carbon in a range greater than or equal to 20 atomic percent and less than or equal to 50 atomic percent relative to boron.
   (7)

The storage element according to any one of (3) to (6), in which
the first heat shield layer, the second heat shield layer, or both contain silicon in a range greater than or equal to 20 atomic percent and less than 60 atomic percent relative to boron.
   (8)

The storage element according to any one of (3) to (7), in which
the first heat shield layer, the second heat shield layer, or both contain germanium.
   (9)

The storage element according to any one of (3) to (7), in which
the first heat shield layer, the second heat shield layer, or both contain tungsten.
   (10)

The storage element according to (4), in which
the first heat shield layer, the second heat shield layer, or both contain tungsten, and
a concentration of tungsten is in a range greater than or equal to 1 atomic percent and less than 5 atomic percent relative to boron.
   (11)

The storage element according to any one of (2) to (4) and (6) to (10), in which
a main component of the first interface layer, the second interface layer, or both is tungsten or tungsten nitride.
   (12)

The storage element according to any one of (2) to (4) and (6) to (11), in which
the first heat shield layer, the second heat shield layer, or both include a single-layer film containing boron.
   (13)

The storage element according to any one of (2) to (4) and (6) to (11), in which
the first heat shield layer, the second heat shield layer, or both include a composite film in which a first film containing boron and a second film containing no boron are stacked.
   (14)

The storage element according to any one of (2) to (4) and (6) to (13), in which
a thickness of the first heat shield layer, the second heat shield layer, or both is less than or equal to half of a thickness of the resistance change layer.
   (15)

A storage device including a storage element, the storage element including:
a first electrode;
a resistance change layer that is formed on the first electrode, contains at least tellurium, antimony, and germanium, and is changeable in a resistance value;
a first interface layer that is formed between the first electrode and the resistance change layer; and
a first heat shield layer that is formed between the first electrode and the first interface layer, has electrical conductivity, contains boron, and blocks heat transfer from the resistance change layer.
   (16)

The storage device according to (15), in which
the storage element further includes:
a second electrode that is formed on the resistance change layer on an opposite side to the first electrode;
a second interface layer that is formed between the second electrode and the resistance change layer; and
a second heat shield layer that is formed between the second electrode and the second interface layer, has electrical conductivity, and blocks heat transfer from the resistance change layer.
   (17)
The storage device according to (16), in which the second heat shield layer contains boron.
   (18)

The storage device according to any one of (15) to (17), including:
the first wiring line that extends in a first direction;
a second wiring line that extends in a second direction intersecting the first direction; and
a memory cell that is disposed at an intersection between the first wiring line and the second wiring line, in which
the memory cell includes
the storage element, and
a switching element coupled to the storage element in series.
   (19)

The storage device according to (16), in which
the first wiring line is formed integrally with the first electrode or the second wiring line is formed integrally with the second electrode.
   (20)

The storage device according to (18) or (19), in which
the switching element contains at least one chalcogen element selected from tellurium, selenium, and sulfur.

The present application claims the benefit of Japanese Priority Patent Application JP 2021-186576 filed with the Japan Patent Office on Nov. 16, 2021, the entire contents of which are incorporated herein by reference.

It should be understood by those skilled in the art that various modifications, combinations, sub-combinations and alterations may occur depending on design requirements and other factors insofar as they are within the scope of the appended claims or the equivalents thereof.

1. A storage element comprising:
a first electrode;
a resistance change layer that is formed on the first electrode, contains at least tellurium, antimony, and germanium, and is changeable in a resistance value;
a first interface layer that is formed between the first electrode and the resistance change layer, and
a first heat shield layer that is formed between the first electrode and the first interface layer, has electrical conductivity, contains boron, contains silicon in a range greater than or equal to 20 atomic percent and less than 60 atomic percent relative to boron, and blocks heat transfer from the resistance change layer.

2. The storage element according to claim 1, further comprising:
a second electrode that is formed on the resistance change layer on an opposite side to the first electrode;
a second interface layer that is formed between the second electrode and the resistance change layer; and
a second heat shield layer that is formed between the second electrode and the second interface layer, has electric conductivity, and blocks heat transfer from the resistance change layer.

3. The storage element according to claim 2, wherein
the second heat shield layer contains boron.

4. The storage element according to claim 3, wherein
the first heat shield layer, the second heat shield layer, or both contain carbon.

5. The storage element according to claim 1, wherein
the first heat shield layer contains carbon in a range greater than or equal to 20 atomic percent and less than or equal to 50 atomic percent relative to boron.

6. The storage element according to claim 3, wherein
the second heat shield layer contains carbon in a range greater than or equal to 20 atomic percent and less than or equal to 50 atomic percent relative to boron.

7. (canceled)

8. The storage element according to claim 3, wherein
the first heat shield layer, the second heat shield layer, or both contain germanium.

9. The storage element according to claim 3, wherein
the first heat shield layer, the second heat shield layer, or both contain tungsten.

10. The storage element according to claim 4, wherein
the first heat shield layer, the second heat shield layer, or both contain tungsten, and
a concentration of tungsten is in a range greater than or equal to 1 atomic percent and less than 5 atomic percent relative to boron.

11. The storage element according to claim 2, wherein
a main component of the first interface layer, the second interface layer, or both is tungsten or tungsten nitride.

12. The storage element according to claim 3, wherein
the first heat shield layer, the second heat shield layer, or both include a single-layer film containing boron.

13. The storage element according to claim 3, wherein
the first heat shield layer, the second heat shield layer, or both include a composite film in which a first film containing boron and a second film containing no boron are stacked.

14. The storage element according to claim 3, wherein
a thickness of the first heat shield layer, the second heat shield layer, or both is less than or equal to half of a thickness of the resistance change layer.

15. A storage device comprising a storage element, the storage element including:
a first electrode;
a resistance change layer that is formed on the first electrode, contains at least tellurium, antimony, and germanium, and is changeable in a resistance value;
a first interface layer that is formed between the first electrode and the resistance change layer, and
a first heat shield layer that is formed between the first electrode and the first interface layer, has electrical conductivity, contains boron, contains silicon in a range greater than or equal to 20 atomic percent and less than 60 atomic percent relative to boron, and blocks heat transfer from the resistance change layer.

16. The storage device according to claim 15, wherein
the storage element further includes:
a second electrode that is formed on the resistance change layer on an opposite side to the first electrode;
a second interface layer that is formed between the second electrode and the resistance change layer; and
a second heat shield layer that is formed between the second electrode and the second interface layer, has electrical conductivity, and blocks heat transfer from the resistance change layer.

17. The storage device according to claim 16, wherein
the second heat shield layer contains boron.

18. The storage device according to claim 16, comprising:
the first wiring line that extends in a first direction;
a second wiring line that extends in a second direction intersecting the first direction; and
a memory cell that is disposed at an intersection between the first wiring line and the second wiring line, wherein
the memory cell includes
the storage element, and
a switching element coupled to the storage element in series.

19. The storage device according to claim 18, wherein
the first wiring line is formed integrally with the first electrode, or the second wiring line is formed integrally with the second electrode.

20. The storage device according to claim 18, wherein
the switching element contains at least one chalcogen element selected from tellurium, selenium, and sulfur.
